(19) United States
(12) Patent Application Publication
(10) Pub. No.: US 2017/0121847 A1
(43) Pub. Date: May 4, 2017

(54) WAFER CARRIER HAVING THERMAL UNIFORMITY-ENHANCING FEATURES

(71) Applicant: Veeco Instruments Inc., Plainview, NY (US)

(72) Inventors: Eric Armour, Pennington, NJ (US); Sandeep Krishnan, Jersey City, NJ (US); Alex Zhang, Plainview, NY (US); Bojan Mitrovic, Somerset, NJ (US); Alexander Gurary, Bridgewater, NJ (US)

(21) Appl. No.: 15/403,709

(22) Filed: Jan. 11, 2017

Related U.S. Application Data
(62) Division of application No. 14/297,244, filed on Jun. 5, 2014.
(60) Provisional application No. 61/831,496, filed on Jun. 5, 2013.

(51) Int. Cl. C30B 25/12; C23C 16/46; C23C 16/458; C30B 25/10

(52) U.S. Cl. CPC C30B 25/12; C30B 25/105; C23C 16/46; C23C 16/4584

(57) ABSTRACT

A wafer carrier assembly for use in a system for growing epitaxial layers on one or more wafers by chemical vapor deposition (CVD), the wafer carrier assembly includes a wafer carrier body formed symmetrically about a central axis, and including a generally planar top surface that is situated perpendicularly to the central axis and a planar bottom surface that is parallel to the top surface. At least one wafer retention pocket is recessed in the wafer carrier body from the top surface. Each of the at least one wafer retention pocket includes a floor surface and a peripheral wall surface that surrounds the floor surface and defines a periphery of that wafer retention pocket. At least one thermal control feature includes an interior cavity or void formed in the wafer carrier body and is defined by interior surfaces of the wafer carrier body.

### CROSS-REFERENCE TO RELATED APPLICATIONS

This Application is a continuation of copending U.S. patent application Ser. No. 14/297,244, which claims the benefit of U.S. Provisional Application No. 61/831,496, filed June 5, 2013, the disclosures of which are incorporated by reference herein in their entirety.

### BACKGROUND

The present invention relates to wafer processing apparatus, to wafer carriers for use in such processing apparatus, and to methods of wafer processing.

Many semiconductor devices are formed by epitaxial growth of a semiconductor material on a substrate. The substrate typically is a crystalline material in the form of a disc, commonly referred to as a “wafer.” For example, devices formed from compound semiconductors such as III-V semiconductors typically are formed by growing successive layers of the compound semiconductor using metal organic chemical vapor deposition or “MOCVD.” In this process, the wafers are exposed to a combination of gases, typically including a metal organic compound and a source of a group V element which flow over the surface of the wafer while the wafer is maintained at an elevated temperature. One example of a III-V semiconductor is gallium nitride, which can be formed by reaction of an organo-gallium compound and ammonia on a substrate having a suitable crystal lattice spacing, as for example, a sapphire wafer. Typically, the wafer is maintained at a temperature on the order of 500-1200° C. during deposition of gallium nitride and related compounds.

Composite devices can be fabricated by depositing numerous layers in succession on the surface of the wafer under slightly different reaction conditions, as for example, additions of other group III or group V elements to vary the crystal structure and bandgap of the semiconductor. For example, in a gallium nitride based semiconductor, indium, aluminum or both can be used in varying proportion to vary the bandgap of the semiconductor. Also, p-type or n-type dopants can be added to control the conductivity of each layer. After all of the semiconductor layers have been formed and, typically, after appropriate electric contacts have been applied, the wafer is cut into individual devices. Devices such as light-emitting diodes (“LEDs”), lasers, and other electronic and optoelectronic devices can be fabricated in this way.

In a typical chemical vapor deposition process, numerous wafers are held on a device commonly referred to as a wafer carrier so that a top surface of each wafer is exposed at the top surface of the wafer carrier. The wafer carrier is then placed into a reaction chamber and maintained at the desired temperature while the gas mixture flows over the surface of the wafer carrier. It is important to maintain uniform conditions at all points on the top surfaces of the various wafers on the carrier during the process. Minor variations in composition of the reactive gases and in the temperature of the wafer surfaces cause undesired variations in the properties of the resulting semiconductor device. For example, if a gallium and indium nitride layer is deposited, variations in wafer surface temperature will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary. Thus, considerable effort has been devoted in the art heretofore towards maintaining uniform conditions.

One type of CVD apparatus which has been widely accepted in the industry uses a wafer carrier in the form of a large disc with numerous wafer-holding regions, each adapted to hold one wafer. The wafer carrier is supported on a spindle within the reaction chamber so that the top surface of the wafer carrier having the exposed surfaces of the wafers faces upwardly toward a gas distribution element. While the spindle is rotated, the gas is directed downwardly onto the top surface of the wafer carrier and flows across the top surface toward the periphery of the wafer carrier. The used gas is evacuated from the reaction chamber through ports disposed below the wafer carrier. The wafer carrier is maintained at the desired elevated temperature by heating elements, typically electrical resistive heating elements disposed below the bottom surface of the wafer carrier. These heating elements are maintained at a temperature above the desired temperature of the wafer surfaces, whereas the gas distribution element and the walls of the chamber typically are maintained at a temperature well below the desired reaction temperature so as to prevent premature reaction of the gases. Therefore, heat is transferred from the resistive heating element to the bottom surface of the wafer carrier and flows upwardly through the wafer carrier to the individual wafers. Heat is transferred from the wafers and wafer carrier to the gas distribution element and to the walls of the chamber.

Although considerable effort has been devoted in the art heretofore to design an optimization of such systems, still further improvement would be desirable. In particular, it would be desirable to provide better uniformity of temperature across the surface of each wafer, and better temperature uniformity across the entire wafer carrier.

### SUMMARY

One aspect of the present invention provides a wafer carrier comprising a body having oppositely-facing top and bottom surfaces extending in horizontal directions and a plurality of pockets open to the top surface, each such pocket being adapted to hold a wafer with a top surface of the wafer exposed at the top surface of the body, the carrier defining a vertical direction perpendicular to the horizontal directions. The wafer carrier body desirably includes one or more thermal control features such as trenches, pockets, or other cavities within the carrier body.

In one type of embodiment, a thermal control feature is buried within the body of the wafer carrier. In another type of embodiment, a combination of buried and non-buried (i.e., exposed), thermal control features is utilized. In a further embodiment, the thermal control features form a channel that permits the flow of process atmosphere.

In another embodiment, the thermal control features are specifically situated beneath the regions of the wafer carrier that are between the wafer pockets. These thermal control features limit the heat flow to the surface of these regions, thereby keeping those surface portions relatively cooler. In one type of embodiment, the surface temperature of the regions between the pockets is maintained at approximately the temperature of the wafers, thereby avoiding historic flow heating effects.

In another embodiment, a wafer carrier is provided with a through hole beneath the wafer that facilitates direct heating of the wafer. In one such embodiment, the wafer is supported by a heat-isolating support ring. In a related embodiment, the through-hole has an undercut that creates a larger opening at the bottom surface than at the top surface of the wafer carrier. Still further aspects of the invention include wafer processing apparatus incorporating the wafer carriers as discussed above, and methods of processing wafers using such carriers.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

The invention may be more completely understood in consideration of the following detailed description of various embodiments of the invention in connection with the accompanying drawings, in which:

FIG. 1 is a simplified, schematic sectional view depicting chemical vapor deposition apparatus in accordance with one embodiment of the invention.

FIG. 2 is a cross-sectional view diagram illustrating the thermal streamlines within the body of a wafer carrier, including streamlines having a horizontal component that result in a heat blanketing effect that creates a temperature gradient over the surface of the wafers during processing.

FIG. 3 is a cross-sectional view diagram depicting thermal isolating feature according to one embodiment of the invention, in which a bottom plate is added to create a buried cavity within the body of the wafer carrier.

FIG. 4 is a cross-sectional view diagram that illustrates a variation the embodiment of FIG. 3, where the buried cavities are oriented in a primarily horizontal orientation, and are sized and positioned to be located in regions of the wafer carrier other than beneath the pockets according to one type of embodiment.

FIG. 5 is a plan-view diagram of a wafer carrier specifically identifying regions between wafer pockets.

FIG. 6A is a cross-sectional view diagrams illustrating a variation of the embodiment of FIGS. 4-5, where a flat cut is made in the bottom surface of the wafer carrier beneath the regions that lie between the wafer pockets according to one type of embodiment.

FIG. 6B is a cross-sectional view diagrams illustrating a variation of the embodiment of FIGS. 4-5, where a curved cut is made in the bottom surface of the wafer carrier beneath the regions that lie between the wafer pockets according to one type of embodiment.

FIG. 7 illustrates a variation of the embodiment depicted in FIG. 37, where a deep cut is utilized as a thermal feature according to one embodiment.

FIG. 8 illustrates an embodiment where a combination of deep cuts and horizontal channels is utilized.

FIG. 9 illustrates another embodiment, in which a combination of open cuts and buried pocket is utilized.

FIG. 10 illustrates en embodiment in which the thermal isolation feature is filled with a layered stack of solid material.

FIG. 11 illustrates another type of embodiment, which is suitable for wafer carriers that handle silicon wafers.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the character and scope of the invention as defined by the appended claims.

### DETAILED DESCRIPTION OF THE DRAWINGS

Chemical vapor deposition apparatus in accordance with one embodiment of the invention includes a reaction chamber 10 having a gas distribution element 12 arranged at one end of the chamber. The end having the gas distribution element 12 is referred to herein as the “top” end of the chamber 10. This end of the chamber typically, but not necessarily, is disposed at the top of the chamber in the normal gravitational frame of reference. Thus, the downward direction as used herein refers to the direction away from the gas distribution element 12 and the upward direction refers to the direction within the chamber, toward the gas distribution element 12, regardless of whether these directions are aligned with the gravitational upward and downward directions. Similarly, the “top” and “bottom” surfaces of elements are described herein with reference to the frame of reference of chamber 10 and element 12.

Gas distribution element 12 is connected to sources 14 of gases to be used in the CVD process, such as a carrier gas and reactant gases such as a source of a group III metal, typically a metalorganic compound, and a source of a group V element as, for example, ammonia or other group V hydride. The gas distribution element is arranged to receive the various gases and direct a flow of gasses generally in the downward direction. The gas distribution element 12 desirably is also connected to a coolant system 16 arranged to circulate a liquid through the gas distribution element so as to maintain the temperature of the element at a desired temperature during operation. The coolant system 16 is also arranged to circulate liquid through the wall of chamber 10 so as to maintain the wall at a desired temperature. Chamber 10 is also equipped with an exhaust system 18 arranged to remove spent gases from the interior of the chamber through ports (not shown) at or near the bottom of the chamber so as to permit continuous flow of gas in the downward direction from the gas distribution element.

A spindle 20 is arranged within the chamber so that the central axis 22 of the spindle extends in the upward and downward directions. The spindle has a fitting 24 at its top end, i.e., at the end of the spindle closest to the gas distribution element 12. In the particular embodiment depicted, the fitting 24 is a generally conical element. Spindle 20 is connected to a rotary drive mechanism 26 such as an electric motor drive, which is arranged to rotate the spindle about axis 22. A heating element 28 is mounted within the chamber and surrounds spindle 20 below fitting 24. The chamber is also provided with an openable port 30 for insertion and removal of wafer carriers. The foregoing elements may be of conventional construction. For example, suitable reaction chambers are sold commercially under the registered trademark TURBODISC by Veeco Instruments, Inc. of Plainview, N.Y., USA, assignee of the present application.

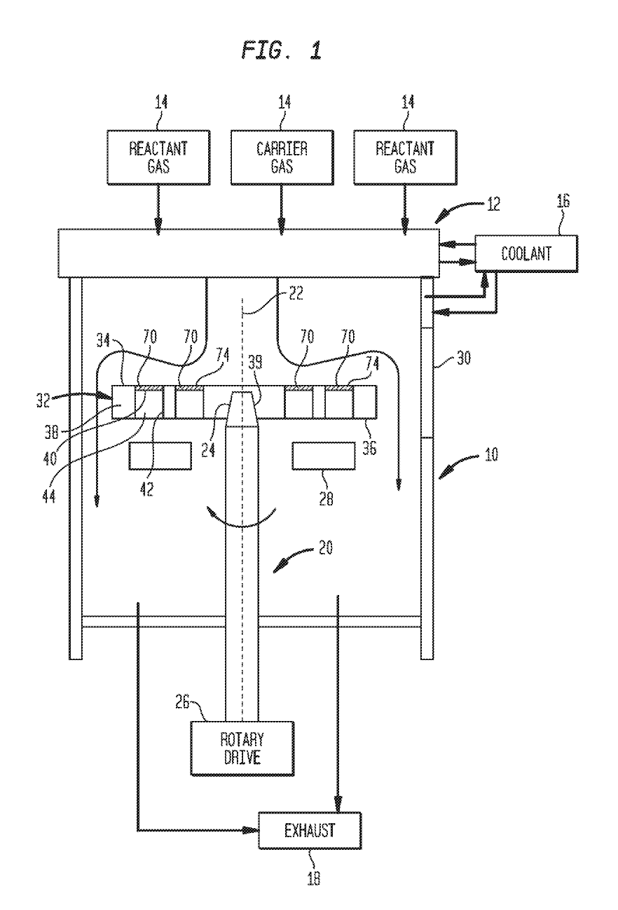

In the operative condition depicted in FIG. 1, a wafer carrier 32 is mounted on the fitting 24 of the spindle. The wafer carrier has a structure which includes a body generally in the form of a circular disc having a central axis 25 extending perpendicular to the top and bottom surfaces. The body of the wafer carrier has a first major surface, referred to herein as the “top” surface 34, and a second major surface, referred to herein as the “bottom” surface 36. The structure of the wafer carrier also has a fitting 39 arranged to engage the fitting 24 of the spindle and to hold the body of the wafer carrier on the spindle with the top surface 34 facing upwardly toward the gas distribution element 12, with the bottom surface 36 facing downwardly toward heating element 28 and away from the gas distribution element. Merely by way of example, the wafer carrier body may be about 465 mm in diameter, and the thickness of the carrier between top surface 34 and bottom surface 32 may be on the order of 15.9 mm. In the particular embodiment illustrated, the fitting 39 is formed as a frustoconical depression in the bottom surface of the body 32. However, as described in copending, commonly assigned US Patent Publication No. 2009-0155028 A1, the disclosure of which is hereby incorporated by reference herein, the structure of the wafer carrier may include a hub formed separately from the body and the fitting may be incorporated in such a hub. Also, the configuration of the fitting will depend on the configuration of the spindle.

The body desirably includes a main portion 38 formed as a monolithic slab of a non-metallic refractory first material as, for example, a material selected from the group consisting of silicon carbide, boron nitride, boron carbide, aluminum nitride, alumina, sapphire, quartz, graphite, and combinations thereof, with or without a refractory coating as, for example, a carbide, nitride or oxide.

The body of the wafer carrier has a central region 27 at and near the central axis 25, a pocket or wafer-holding region 29 encircling the central region and a peripheral region 31 encircling the pocket region and defining the periphery of the body. The peripheral region 31 defines a peripheral surface 2 extending between the top surface 34 and bottom surface 36 at the outermost extremity of the body.

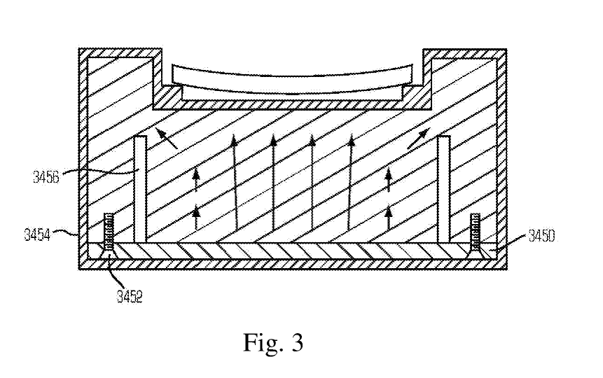

The body of the carrier defines a plurality of circular pockets 40 open to the top surface in the pocket region 29. As best seen in FIG. 1, the main portion 38 of the body defines a substantially planar top surface 34. The main portion 38 has holes 42 extending through the main portion, from the top surface 34 to the bottom surface 36. A minor portion 44 is disposed within each hole 42. The minor portion 44 disposed within each hole defines a floor surface 46 of the pocket 40, the floor surface being recessed below the top surface 34. The minor portions 44 are formed from a second material, preferably a non-metallic refractory material consisting of silicon carbide, boron nitride, boron carbide, aluminum nitride, alumina, sapphire, quartz, graphite, and combinations thereof, with or without a refractory coating as, for example, a carbide, nitride or oxide. The second material desirably is different from the first material constituting the main portion. The second material may have a thermal conductivity higher than the thermal conductivity of the first material. For example, where the main portion is formed from graphite, the minor portions may be formed from silicon carbide. The minor portions 44 and the main portion 38 cooperatively define the bottom surface 36 of the body. In the particular embodiment depicted in FIG. 3, the bottom surface of the main portion 38 is planar, and the bottom surfaces of the minor portions 44 are coplanar with the bottom surface of the main portion, so that the bottom surface 36 is planar.

The minor portions 44 are frictionally engaged with the walls of the holes 42. For example, the minor portions may be press-fit into the holes or shrink-fitted by raising the main portion to an elevated temperature and inserting cold minor portions into the holes. Desirably, all of the pockets are of uniform depth. This uniformity can be achieved readily by forming all of the minor portions to a uniform thickness as, for example, by grinding or polishing the minor portions.

There is a thermal barrier 48 between each minor portion 44 and the surrounding material of the main portion 38. The thermal barrier is a region having thermal conductivity that is lower than the thermal conductivity of the bulk material of the main portion. The thermal barrier includes a macroscopic gap 48, as, for example, a gap about 100 microns or more thick, formed by a groove in the wall of the main portion 38 defining the hole 42. This gap contains a gas such as air or the process gasses encountered during operation, and hence has much lower thermal conductivity than the neighboring solid materials.

The abutting surfaces of the minor portions 44 and main portion 38 also define parts of the thermal barrier. Although these surfaces abut one another on a macroscopic scale, neither surface is perfectly smooth. Therefore, there will be microscopic, gas-filled gaps between parts of the abutting surfaces. These gaps will also impede thermal conduction between the minor portion 44 and main portion 38.

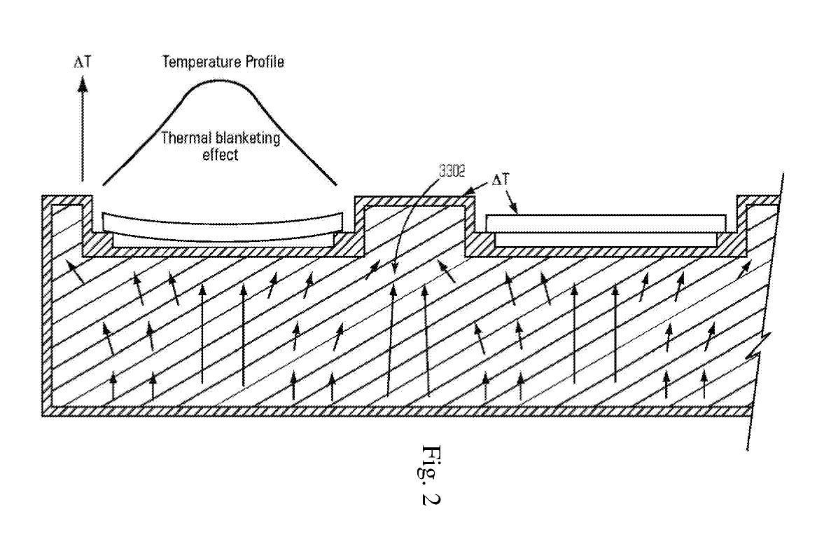

In a CVD system, the wafer carrier is predominantly heated by radiation, with the radiant energy impinging on the bottom of the carrier. A cold-wall CVD reactor design (i.e., one that uses non-isothermal heating) creates conditions in the reaction chamber where a top surface of the wafer carrier is cooler than the bottom surface. With reference to FIG. 2, without wafers present, the thermal streamlines 3302 depicted as arrows inside the wafer carrier cross-section shown extend vertically from the bottom to the top surface in the carrier and are parallel for most of the carrier bulk. The top surface of the carrier is cooler, with the thermal energy being radiated upwards (towards the cold-plate, confined inlet and shutter). Without wafers on the carrier, convective cooling of the wafer carrier (from the gas streamlines passing over the carrier) is a secondary effect.

The degree of radiative emission from the wafer carrier is determined by the emissivity of the carrier and the surrounding components. Changing the interior components of the reaction chamber such as the cold-plate, CIF, shutter, and other regions, to a higher emissivity material (i.e. black coating or rougher coatings instead of the current shiny silver portions) can result in increased radiative heat transfer. Likewise, reducing the emissivity of the carrier (whitening or other phenomenon) will result in less radiative heat removal from the carrier. The degree of convective cooling of the carrier surface is driven by the overall gas flow pumping through the chamber, along with the heat capacity of the gas mixture (H2, N2, NH3, OMs, etc.)

Introducing a wafer, such as a sapphire wafer, in a pocket enhances the transverse component of the thermal streamlines, resulting in a “blanketing” effect. For instance, consider a simple case of a single wafer on a carrier. In this case, there are no thermal packing (geometrical) issues resulting from the presence of nearby wafers. Thus, the thermal streamlines take a path of least resistance creating a lateral gradient, as illustrated with the non-parallel arrows in FIG. 2. This phenomenon results in a radial thermal profile at the pocket floor which is hotter in the center and lower temperature towards the other radius of the pocket. Approaches to reducing this lateral gradient effect are described above, using the thermal barriers, or trenches, e.g., trenches 41, to thermally isolate the pockets. With such thermal barriers or trenches, formed by removing material from the bottom surface of the wafer carrier, the lateral heat transfer is limited to the small region above the trenches/thermal barriers.

One practical issue with this construction is that the trenches, exposed on the bottom of the carrier, reduce the structural integrity of the carrier. Thus, in a related embodiment, a multi-piece isolation carrier is provided, whereby a bottom plate is affixed to the bulk wafer carrier portion to provide structural support. For instance, as illustrated in FIG. 3, a bottom plate 3450 is attached to the wafer carrier using screws 3452. The screws 3452 can be made from the same material as the wafer carrier bulk, e.g., graphite, so that thermal stresses can be avoided. Other suitable materials are also contemplated, such as metals, ceramics, or composite materials, which have a coefficient of thermal expansion that is comparable to that of the wafer carrier body.

After the bottom plate 3450 is affixed, it can then be encapsulated along with the rest of the wafer carrier with the SiC coating 3454, thereby creating a stronger, unitary, wafer carrier. This assembled wafer carrier has one or more interior cavities 3456 that is completely buried (i.e., enclosed on all sides by the wafer carrier's body). A variety of interior cavity sizes, shapes, and orientations are contemplated according to various embodiments. For instance, any of the above-described trenches, or thermal barriers, can be buried according to this type of embodiment.

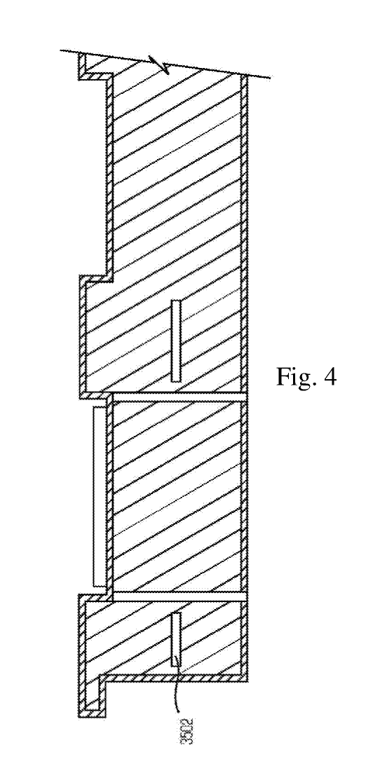

FIG. 4 schematically illustrates a variation of this type of embodiment. Here, buried cavities 3502, also referred to as air pockets 3502, are oriented in a primarily horizontal orientation, and are sized and positioned to be located in regions of the wafer carrier other than beneath the pockets.

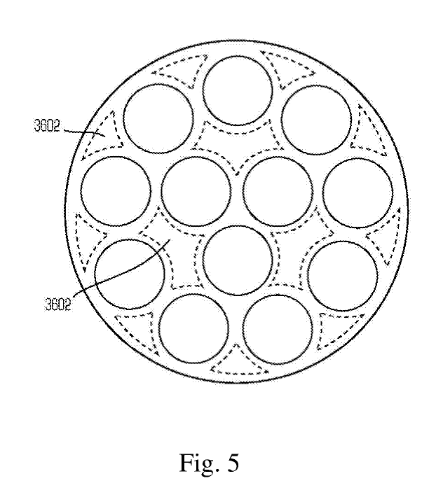

FIG. 5 is a diagram of a wafer carrier illustrating an exemplary set of regions 3602 between the pockets where the buried cavities of the embodiment of FIG. 4 may be situated.

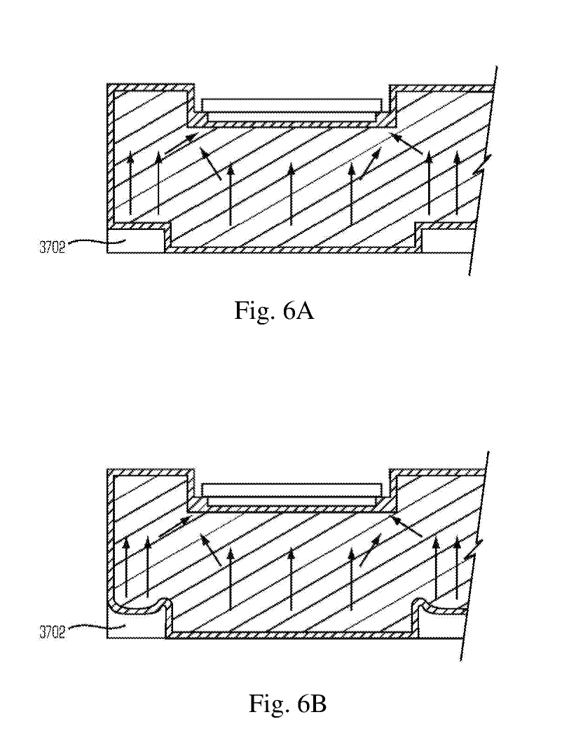

FIGS. 6A and 6B are cross-sectional diagrams illustrating a variation of the embodiment of FIGS. 4-5. Here, a buried cavity is not utilized; rather, a cut 3702 is made in the bottom surface of the wafer carrier beneath the regions 3602 that lie between the wafer pockets. The cut 3702 can be described as a recess in the bottom surface of the wafer carrier. In various approaches, the depth of the cut can be flat, as shown in FIG. 6A, or curved, as shown in FIG. 6B. The depth profile of cut 3702 can be determined from experimental data that may vary depending on the wafer carrier size, wafer size, number of wafer pockets, relative positioning of wafer pockets, wafer carrier thickness, reaction chamber construction, and other factors.

In the case of multi-wafer pocket geometries with non-concentric pocket locations, the thermal profile becomes more complicated, as the convective cooling is dependent upon the historical gas streamline path passing over both the wafer carrier and wafer regions. For high-speed rotating disc reactors, the gas streamlines spiral outward from inner to outer radius in a generally tangential direction. In this case, when the gas streamline is passing over the exposed portion of the wafer carrier (such as the regions 3602 between the wafers), it is heated up relative to the regions where it is passing over the wafers. In general, these regions 3602 are quite hot relative to the other regions of the carrier, as the heat flux streamlines due to the blanketing effect have channeled the streamlines into this region. Thus, the gas paths passing over the webs create a tangential gradient in temperature due to the convective cooling, which is hotter at the leading edge (entry of the fluid streamline to the wafer) relative to the trailing edge (exit of the fluid streamline over the wafer).

In another embodiment, this tangential gradient can be reduced by lowering the wafer carrier surface temperature (within the non-pocket regions 3602) to a temperature closer to that of the growth surface of the wafers. Utilizing the isolation features described above reduces the thermal streamline concentration into the web region.

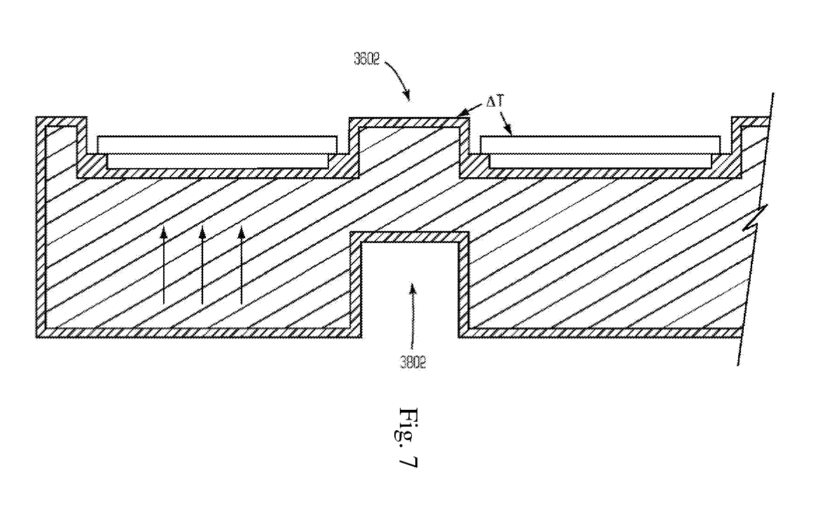

FIG. 7 illustrates another embodiment, which is a variation of the embodiment depicted in FIGS. 6A-6B. Here, a cut 3802 is made beneath each region 3602 between wafer pockets. Cut 3802 is substantially deeper, extending most of the way through the wafer carrier's depth. In a related embodiment, a bottom plate, such as plate 3450, can be added as depicted in FIG. 3, to create buried cavities from cuts 3802.

An isolation cut such as the one illustrated in FIG. 7 will generate a local temperature drop due to decreased conductance of the gap (and consequently lower heat flux exiting from the carrier surface above the cut). However, increasing the width of the cut can increase direct radiative heating of the roof of the cut, and reverse the desired effect. Accordingly, in a related aspect of the invention, the heating of the wafer carrier regions in the vicinity of the isolation features is managed. According to one approach, the width and geometry of the isolation regions is specifically defined to limit direct heating of the top surface of the cut.

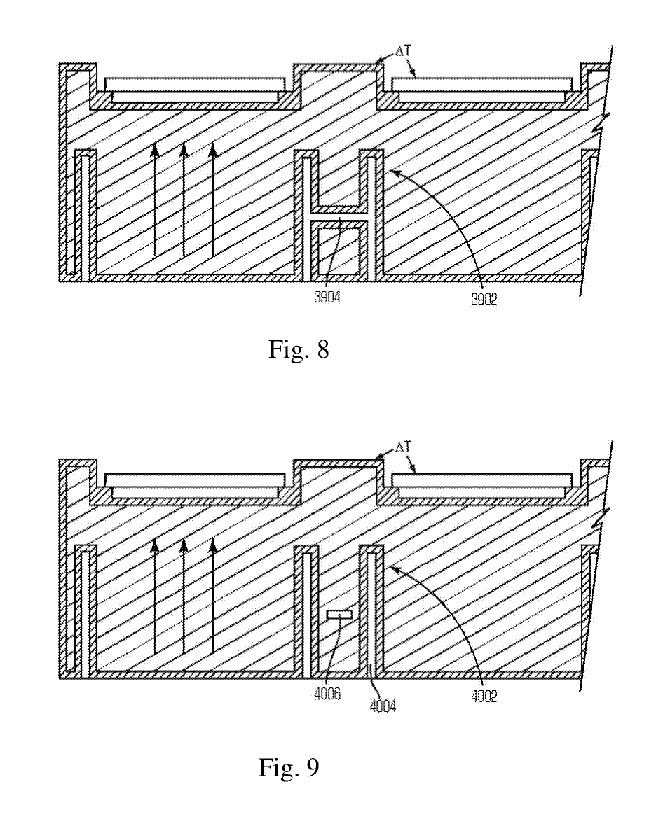

FIG. 8 illustrates one such embodiment, where a combination 3902 of deeper cuts and horizontal channels is utilized. Notably, the interior surface of combination 3902 is coated with SiC. The combination 3902 permits the process atmosphere to enter, and flow through, such that the regions 3602 beneath the non-pocket areas remain relatively cooler.

FIG. 9 illustrates another embodiment, in which a combination 4002 of open cuts 4004 and buried pocket 4006 is constructed. Compared to the approach of FIG. 8, this approach manages the temperature within the wafer carrier body somewhat differently by taking advantage of the thermal-insulating properties of a gas-filled pocket, yet limiting the flow of process gas through the isolation portions.

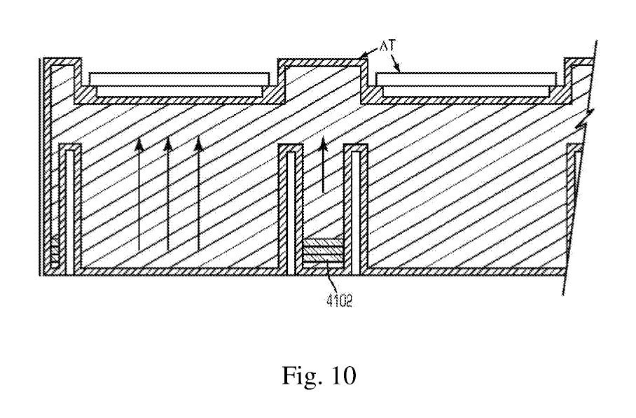

In another related embodiment, as depicted in FIG. 10, stacks of solid material 4102 are inserted into portions of the isolation features. The solid material can be layered pieces of the same material, or can be a sandwiched structure using more than one material. Even a material that is the same as the wafer carrier bulk (e.g., graphite), will provide reduced thermal transfer since the conductance transfer across a material interface is less efficient than a continuously bonded material. One advantage of including solid stacks is that they can be manufactured to be structurally stronger than open air cuts depicted in some of the embodiments above. In various embodiments, the layered structures are secured using suitable fastening means, e.g., screws, adhesives, etc.

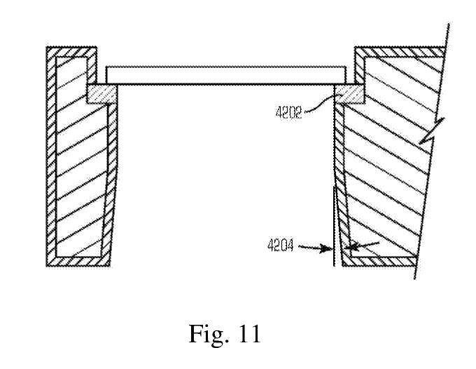

FIG. 11 illustrates another type of embodiment, which is suitable for wafer carriers that handle silicon wafers. In general, most of the above discussion can apply to silicon wafer platforms; however the opacity of the wafers affects some of the thermal transfer characteristics. Typically, silicon wafers have larger diameters than sapphire (which are relatively quite small at 150-200 mm currently). The larger diameter of silicon wafers (e.g., 300 mm+) results in a stronger blanketing effect. In addition, there is both conductive and radiative transfer of heat from wafer pocket floor to the Si substrate. Heat removal at the top surface of the Si wafer is also a combination of radiative and convective transfer. A further complication of the Si thermal characteristics is that typically the film stresses induced during the lattice mismatch and CTE-mismatched epitaxial layers result in fairly large concave or convex curvatures, which greatly affect the thermal transfer across the gas gaps between pocket and wafer.

Accordingly, in one embodiment, as depicted in FIG. 11, the pocket floor is eliminated entirely. Here, direct radiative coupling of the heaters to the Silicon wafer can be achieved, and variation in air-gap distance due to curvature changes is rendered negligible. The wafer is supported by a shelf that provides a bottom pocket floor surface only near the very edges of the wafer.

In related embodiments, two additional features are provided. The silicon wafer is situated on a thermally-isolating support ring 4202 to limit direct conductive heat transfer to the wafer's edges. The support ring 4202 can be made from any suitable material, such as a ceramic material (e.g., quartz). Also, the interior walls are undercut such that the opening is larger at the bottom than at the top, as depicted with reference numeral 4204. The interior walls in one embodiment have a frustoconical shape. This arrangement provides for more complete illumination of the wafer from the heating element situated below. A suitable undercut angle can be between 5 and 15 degrees according to one embodiment.

The embodiments above are intended to be illustrative and not limiting. Additional embodiments are within the claims. In addition, although aspects of the present invention have been described with reference to particular embodiments, those skilled in the art will recognize that changes can be made in form and detail without departing from the scope of the invention, as defined by the claims.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention may comprise a combination of different individual features selected from different individual embodiments, as will be understood by persons of ordinary skill in the art.

Any incorporation by reference of documents above is limited such that no subject matter is incorporated that is contrary to the explicit disclosure herein. Any incorporation by reference of documents above is further limited such that no claims that are included in the documents are incorporated by reference into the claims of the present Application. The claims of any of the documents are, however, incorporated as part of the disclosure herein, unless specifically excluded. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

1. A wafer carrier assembly for use in a system for growing epitaxial layers on one or more wafers by chemical vapor deposition (CVD), the wafer carrier assembly comprising:
a wafer carrier body formed symmetrically about a central axis, and including a generally planar top surface that is situated perpendicularly to the central axis and a bottom surface that is substantially parallel to the top surface;
at least two wafer retention regions in the wafer carrier body, each of the at least two wafer retention regions including a bore through the wafer carrier body extending from the top surface through the bottom surface and defined by an interior peripheral surface of the wafer carrier body, the at least two wafer retention regions further including a support shelf recessed below the top surface and situated along the interior peripheral surface, the support shelf being adapted to retain a wafer within the wafer retention region when subjected to rotation about the central axis;
a cutaway portion of the bottom surface defined in the wafer carrier to form a thermal barrier, wherein the thermal barrier reduces thermal transfer between the two wafer retention regions and extends into the wafer carrier body from the bottom surface; and
a plate configured to attach to the bottom surface such that the thermal barrier is arranged between the bottom surface and the plate.

2. The wafer carrier assembly of claim 1, further comprising:
a support ring is formed from a material having a thermal conductivity that is less than the thermal conductivity of the wafer carrier body, the support ring being situated on the support shelf and arranged to insulate a wafer from the interior peripheral surface.

3. The wafer carrier assembly of claim 1, wherein the bore has a larger opening at the bottom surface than at the top surface, and wherein the interior peripheral surface has a frustoconical form.

4. A wafer carrier assembly for use in a system for growing epitaxial layers on one or more wafers by chemical vapor deposition (CVD), the wafer carrier assembly comprising:
a wafer carrier body formed symmetrically about a central axis, and including a generally planar top surface that is situated perpendicularly to the central axis and a bottom surface that is substantially parallel to the top surface;
a plurality of wafer retention pockets recessed in the wafer carrier body from the top surface, each of the plurality of wafer retention pockets including a floor surface and a peripheral wall surface that surrounds the floor surface and defines a periphery of that wafer retention pocket, the wafer retention pocket being adapted to retain a wafer within the periphery when subjected to rotation about the central axis;
at least one thermal control feature that includes an interior cavity formed in the wafer carrier body at the bottom surface;
a plate configured to attach to the bottom surface such that, the interior cavity is enclosed by the bottom surface and the plate;
wherein the at least one thermal control feature has a lower thermal conductivity than the wafer body and is configured to thermally separate at least two of the plurality of wafer retention pockets.

5. The wafer carrier assembly of claim 4, wherein the at least one thermal control feature is situated between the bottom surface and the top surface but not between the bottom surface and the floor surface.

6. The wafer carrier assembly of claim 4, wherein the at least one thermal control feature contains a gas.

7. The wafer carrier assembly of claim 4, wherein the at least one thermal control feature has a height defined along an axis parallel to the central axis, and a width defined perpendicularly to the central axis, and wherein the width of the at least one thermal control feature is greater than the height.

8. (canceled)

9. The wafer carrier assembly of claim 4, wherein the at least one thermal control feature comprises a plurality of layers of a solid material.

10. The wafer carrier assembly of claim 4, wherein the at least one thermal control feature comprises a channel that permits gas flow, the channel including a first opening and a second opening to an exterior of the wafer carrier body.

11. Apparatus for growing epitaxial layers on one or more wafers by chemical vapor deposition (CVD), comprising:
a reaction chamber;
a rotatable spindle having an upper end disposed inside the reaction chamber;
a wafer carrier for transporting and providing a support for the one or more wafers, the wafer carrier being centrally and detachably mounted on the upper end of the spindle and being in contact therewith at least in the course of a CVD process; and
a radiant heating element disposed under the wafer carrier for heating thereof; wherein the wafer carrier comprises
a wafer carrier body formed symmetrically about a central axis, and including a generally planar top surface that is situated perpendicularly to the central axis and a bottom surface that is substantially parallel to the top surface;
a plurality of wafer retention pockets recessed in the wafer carrier body from the top surface, each of the plurality of wafer retention pockets including a floor surface and a peripheral wall surface that surrounds the floor surface and defines a periphery of that wafer retention pocket, the wafer retention pocket being adapted to retain a wafer within the periphery when subjected to rotation about the central axis;
at least one thermal control feature that includes an interior cavity formed in the wafer carrier body and defined by interior surfaces of the wafer carrier body
a plate configured to attach to the bottom surface such that the thermal control feature is arranged between the bottom surface and the plate;
wherein the at least one thermal control feature has a lower thermal conductivity than the wafer body such that heat flow in the wafer carrier body caused by operation of the radiant heating element tends to concentrate in regions other than the regions above the at least one thermal control feature.

12-15. (canceled)
